(19) United States
(12) Patent Application Publication
(10) Pub. No.: US 2006/0113524 A1
(43) Pub. Date: Jun. 1, 2006

(54) Polymer-based transistor devices, methods, and systems

(76) Inventors: Colin Bill, Cupertino, CA (US); Michael A. Van Buskirk, Saratoga, CA (US); Zhida Lan, Cupertino, CA (US); John S. Ennals, Cupertino, CA (US); Tzu-Ning Fang, Palo Alto, CA (US)

Correspondence Address: AMIN & TUROCY, LLP, 1900 EAST 9TH STREET, NATIONAL CITY CENTER, 24TH FLOOR,, CLEVELAND, OH, 44114, US

(21) Appl. No.: 11/000,685

(22) Filed: Dec. 1, 2004

(51) Int. Cl. H01L 29/08

(52) U.S. Cl. 257/40

(57) ABSTRACT

One aspect of the present invention relates to a semiconductor transistor device with an annular gate surrounding, at least in part, a channel that conducts current between a first and second source/drain. Another aspect of the present invention relates to a semiconductor transistor device having an annular gate and containing a channel composed of a polymer material. Yet another aspect of the present invention relates to fabrication of a device utilizing a polymer channel surrounded, at least in part, by an annular gate. Still yet another aspect of the present invention relates to a system with a means to control (and/or amplify) current via an annular gate surrounding a channel which conducts current between a first and second source/drain. Still other aspects of the present invention include devices incorporating the present invention's devices, systems and methods such as computers, memory, handhelds and electronic devices.

### TECHNICAL FIELD

The present invention relates generally to semiconductor transistor devices and, in particular, to polymer-based transistor devices.

### BACKGROUND ART

Semiconductors have permeated into every aspect of modern society. They are the building blocks used to create everything from the information super-highway to the electronic timer in the family toaster. Generally, any device that is considered “electronic” utilizes semiconductors. These often-unseen components help to reduce the daily workload, increase the safety of our air traffic control systems, and even let us know when it is time to add softener to the washing machine. Modern society has come to rely on these devices in almost every product produced today. And, as we progress further into a technologically dependent society, the demand for increased device speeds, capacity and functionality drive semiconductor manufacturers to push the edge of technology even further.

One common type of semiconductor is the transistor. This device revolutionized the electronics industry after its invention in 1947. Prior to this time, circuits requiring amplification of signals were forced to utilize bulky vacuum tubes for this task. Transistors provided signal amplification at less than a tenth the size of vacuum tubes. This led to new portable devices, such as the transistor radio, that before the transistor could not have been transported easily. Communication devices depend heavily on amplification of signals to operate properly. Big bulky equipment was suddenly reduced in size to handy portable units. Thus, the transistor helped to create a new world of electronic devices that could fit and be utilized in ways never before possible, replacing the fragile and bulky vacuum tubes.

A transistor is a tiny electronic component that changes a small input signal into a large output signal. The process of changing a small signal into a large signal while retaining the integrity of the small signal is known as amplification. For instance, if a weak radio signal is received by an antenna, the signal can be processed by a transistor and amplified such that a human being can hear the transmitted signal. The transistor is typically comprised of three layers of semiconductor material. The amplification process is accomplished by applying the weak signal across the inner layer to one of the outer layers. This creates a duplicate but much stronger signal between the two outer layers. Typically, the transistor is accompanied by other electronic components to aid in creating a transistor type amplification process.

Transistor technology has progressed steadily since 1947 when they were first discovered. Many different types of transistors have been developed such as junction, FET (field-effect transistor), and MOSFET (metal-oxide semiconductor field-effect transistor). Generally speaking, a transistor is comprised of semiconductor materials that interface with common physical boundaries. The semiconductor materials utilized include gallium-arsenide and germanium which are doped with impurities to make them conductive. An “n-type” semiconductor has excess electrons due to the impurities and a “p-type” semiconductor has a deficiency of electrons, and therefore, an excess of holes. Electrons are negative charge carriers and holes are positive charge carriers.

A junction transistor consists of two outer semiconductors separated by a thin layer of an opposing type of semiconductor material. When the electric potentials on one of the outer layers and the thin layer meet a certain threshold, a small current between the layers occurs. This small current creates a large current between the two outer semiconductor layers, producing current amplification. Junction transistors can be N-P-N or P-N-P. Either type operates in the same fashion, but each operates with different polarities. The transistor can also be employed as a switch.

The FET was developed after the junction transistor and draws virtually no power from an input signal, surmounting a major obstacle of the junction transistor. An FET is comprised of a channel of semiconductor material interposed between two electrodes. The electrodes attached to the ends of the channel are called the source and the drain. The channel contains regions of opposing semiconductor material to that which makes up the electrodes (p-type versus n-type or n-type versus p-type). These regions are in proximity to electrodes called gates. A specific threshold potential applied to the gates impedes current flow between the source and the drain. This is normally referred to as a reverse potential or voltage. Changing the value of this reverse potential alters the resistance of the channel, allowing the reverse potential to regulate the current flow between the source and the drain. Altering the type of composition of the semiconductor material allows for the device to operate with reversed polarities.

Another variation of the FET transistor is the MOSFET. This is a single gate device in which the gate is separated from the channel by a layer of dielectric, typically metal oxide. The gate's electric field penetrates through the dielectric layer and into the channel, controlling the resistance of the current through the channel. A potential applied to the gate of the MOSFET can increase the current flow between the source and the drain and also decrease it.

### SUMMARY OF THE INVENTION

The following is a summary of the invention in order to provide a basic understanding of some aspects of the invention. This summary is not intended to identify key/critical elements of the invention or to delineate the scope of the invention. Its sole purpose is to present some concepts of the invention in a simplified form as a prelude to the more detailed description that is presented later.

The present invention provides semiconductor devices that possess one or more of the following: small size compared to inorganic semiconductor devices, capability to amplify current flow, quick operational response time, lower operating voltages, low cost, high reliability, long life, increased current flow over inorganic semiconductor devices, low temperature processing, light weight, and high density.

One aspect of the present invention relates to a semiconductor transistor device with an annular gate. This increases the amount of channel cross sectional area affected by the annular gate, allowing more current to flow. Thus, for the same given size or density, the present device can amplify (or control) a much greater current, increasing performance and flexibility of the device.

Another aspect of the present invention relates to a semiconductor transistor device containing a channel composed of an organic polymer material. This allows variability in the current handling capabilities of a given device depending upon the current flow characteristics of the polymer material utilized during manufacture, increasing the flexibility of existing manufacturing processes and reducing manufacturing costs.

Organic semiconductor materials (OSM) offer the ability to produce more efficient and enhanced semiconductor devices. Components that were thought to be reaching their molecular limitations as their sizes diminished, are finding new life through the use of OSM. This type of material also allows for smaller and faster semiconductor devices. OSM utilization is allowing the next generation of semiconductor products to advance forward and, at the same time, simplifying the manufacturing process. The combination of inorganic technologies with organic technologies is required to preserve the initial investments facilities have made in semiconductor manufacturing processes, extending their production capabilities.

Yet another aspect of the present invention relates to fabrication of a device utilizing a polymer channel surrounded, at least in part, by an annular gate.

Still yet another aspect of the present invention relates to a system with a means to control (or amplify) current via an annular gate surrounding a channel.

To the accomplishment of the foregoing and related ends, the invention comprises the features hereinafter fully described and particularly pointed out in the claims. The following description and the annexed drawings set forth in detail certain illustrative aspects and implementations of the invention. These are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF DRAWINGS

FIG. 1 is a three dimensional view of a semiconductor device in accordance with an aspect of the present invention.

FIG. 2 is a three dimensional view of a semiconductor device illustrating a first and second source/drain, a channel and a gate in accordance with an aspect of the present invention.

FIG. 3 is a three dimensional view of a semiconductor device showing a first and second source/drain and a channel in accordance with an aspect of the present invention.

FIG. 4 is a cut-away diagram illustrating components and interfaces of a semiconductor device in accordance with an aspect of the present invention.

FIG. 5 is a three dimensional view of a channel of a semiconductor device in accordance with an aspect of the present invention.

FIG. 6 is another cut-away diagram illustrating components, interfaces and electrical characteristics of a semiconductor device in accordance with an aspect of the present invention.

FIG. 7 is a graph illustrating different modal operating characteristics of a semiconductor device in accordance with an aspect of the present invention.

FIG. 8 is a flow diagram illustrating a method of fabricating a semiconductor device in accordance with an aspect of the present invention.

FIG. 9 is another flow diagram illustrating a method of fabricating a semiconductor device in accordance with an aspect of the present invention.

FIG. 10 is a diagram illustrating fabrication of substrate layer and a first dielectric material layer for a semiconductor device in accordance with an aspect of the present invention.

FIG. 11 is a diagram illustrating fabrication of a first source/drain for a semiconductor device in accordance with an aspect of the present invention.

FIG. 12 is a diagram illustrating fabrication of a second dielectric material layer for a semiconductor device in accordance with an aspect of the present invention.

FIG. 13 is a diagram illustrating fabrication of a gate material layer for a semiconductor device in accordance with an aspect of the present invention.

FIG. 14 is a diagram illustrating fabrication of a gate for a semiconductor device in accordance with an aspect of the present invention.

FIG. 15 is another diagram illustrating fabrication of a dielectric material layer for a semiconductor device in accordance with an aspect of the present invention.

FIG. 16 is a diagram illustrating patterning of an inner gate region for a semiconductor device in accordance with an aspect of the present invention.

FIG. 17 is a diagram illustrating fabrication of an inner gate region for a semiconductor device in accordance with an aspect of the present invention.

FIG. 18 is yet another diagram illustrating fabrication of a dielectric material layer for a semiconductor device in accordance with an aspect of the present invention.

FIG. 19 is a diagram illustrating fabrication of a first source/drain contact region for a semiconductor device in accordance with an aspect of the present invention.

FIG. 20 is a diagram illustrating fabrication of a channel for a semiconductor device in accordance with an aspect of the present invention.

FIG. 21 is a diagram illustrating fabrication of a second source/drain for a semiconductor device in accordance with an aspect of the present invention.

FIG. 22 is a topical view illustrating a semiconductor device in accordance with an aspect of the present invention.

### DISCLOSURE OF INVENTION

The present invention is now described with reference to the drawings, wherein like reference numerals are used to refer to like elements throughout. In the following description, for purposes of explanation, numerous specific details are set forth in order to provide a thorough understanding of the present invention. It may be evident, however, that the present invention may be practiced without these specific details. In other instances, well-known structures and devices are shown in block diagram form in order to facilitate describing the present invention.

As used in this application, the term “computer component” is intended to refer to a computer-related entity, either hardware, a combination of hardware and software, software, or software in execution. For example, a computer component may be, but is not limited to being, a process running on a processor, a processor, an object, an executable, a thread of execution, a program, and/or a computer. By way of illustration, both an application running on a server and the server can be a computer component. One or more computer components may reside within a process and/or thread of execution and a component may be localized on one computer and/or distributed between two or more computers.

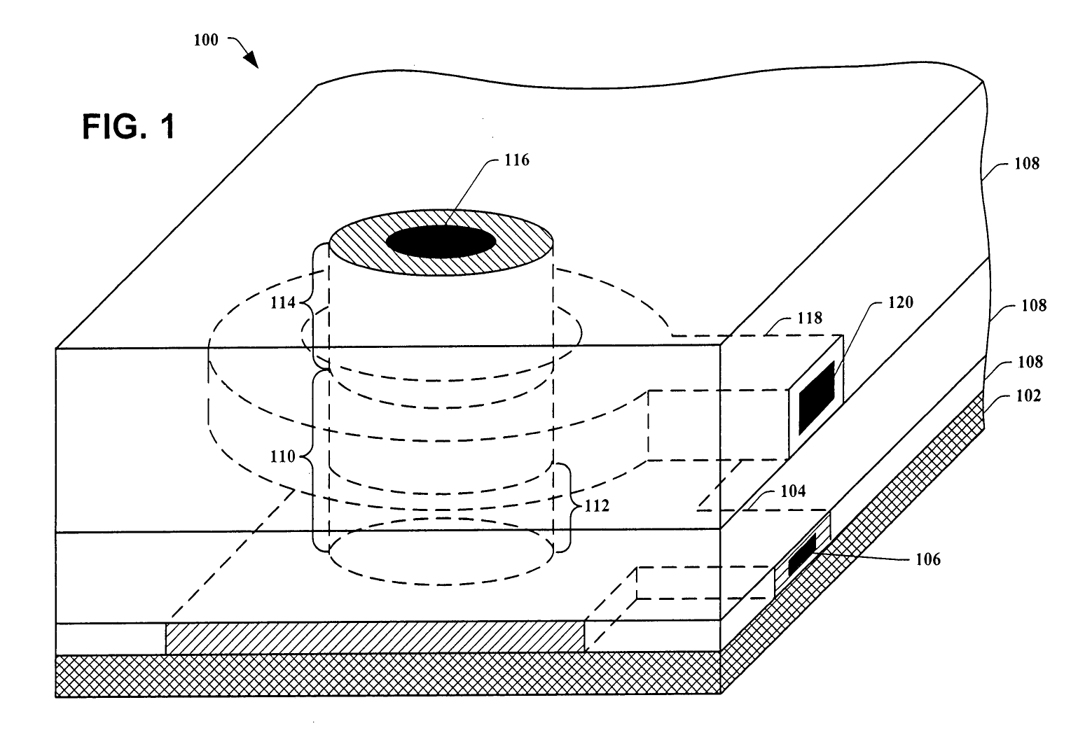

In FIG. 1, a three dimensional view of a semiconductor device 100 in accordance with an aspect of the present invention is illustrated. This view is representative of the components of an aspect of the present invention, however, proportions of the various components (especially apparent thicknesses of dielectric layers) are not exact in order to better illustrate their interrelationships. The device 100 is depicted on a substrate 102 comprised of silicon dioxide (SiO₂) and the like. A first source/drain 104 is shown as a planar layer in FIG. 1 and is comprised of a conductive material. Although illustrated as a planar layer, the first source/drain can also be cylindrical and the like. The first source/drain 104 has a first contact point 106 or a via to allow for electrical connections. The remaining volume in the planar layer containing the first source/drain 104 is generally filled with a dielectric 108 such as oxide and the like. A cylindrical channel 110 makes electrical contact with the first source/drain 104. More dielectric 108 covers the first source/drain 104 and a portion 112 of the channel 110. The channel 110 makes electrical contact with a second source/drain 114. The second source/drain 114 is illustrated as a cylindrical volume, but it can also be a planar layer and the like, and is comprised of a semiconductor material. The second source/drain 114 has a second contact point 116 or a via to allow for electrical connections. An annular gate 118 surrounds at least a portion of the channel 110 and the second source/drain 114. The annular gate 118 has a third contact point 120 or a via to allow for electrical connections. Typically, more dielectric 108 is used to cover the gate 118, the channel 110 and the second source/drain 114 up to, but not including, the second contact point 116.

The term annular in the present invention refers to an element with substantially ring-like properties that may or may not entirely encompass another element. For example, the element can possess characteristics of a hexagon, an octagon, a circle and/or even a square and the like. It can also include, but is not limited to, characteristics of a semi-circle, a partial semi-circle, and a horseshoe-shape and the like. The characteristics are not required to be perfectly symmetrical nor unvarying in dimensions. For example, a tear drop shape with tapering thicknesses and the like are within the scope of the present invention. Annular is representative of an element's relationship to another element in its characteristic of attempting to surround the other element, partially or wholly.

Operationally, a voltage applied to the third contact point 120 induces a current to flow between the second contact point 116 and the first contact point 106. A typical device can have a current gain in an approximate range of 10 to 150 based on the inverse of a frequency of a signal. This produces current amplification which is the forte of all transistors. MOSFET type devices and the present invention also amplify voltages as well. Generally, transistors will accurately amplify an input signal as long as it is operated within its parameters. Some of these parameters include a transistor's operational temperature range and frequency of the signals.

The annular gate 118 is typically comprised of polysilicon material such as polycrystalline silicon. The first and second source/drains are comprised of conductive materials. However, it is not necessary for the first and second source/drains 104, 114 to both be composed of the same conductive material. In one aspect of the present invention, the first and second source/drains 104, 114 are comprised of a conductive material such as aluminum, chromium, copper, germanium, gold, magnesium, manganese, indium, iron, nickel, palladium, platinum, silver, titanium, zinc, alloys thereof, indium-tin oxide, polysilicon, doped amorphous silicon, metal silicides, and the like. Exemplary alloys that can be utilized for the conductive material include Hastelloy®, Kovar®, Invar, Monel®, Inconel®, brass, stainless steel, magnesium-silver alloy, and various other alloys. The thicknesses of the first and second source/drains 104, 114 can vary depending on the implementation and the semiconductor device being constructed. However, some exemplary thickness ranges include about 0.01 μm or more and about 10 μm or less, about 0.05 μm or more and about 5 μm or less, and/or about 0.1 μm or more and about 1 μm or less.

The first and second source/drains 104, 114 can be deposited on the substrate 102 and the channel 110, respectively, in any manner suitable for transistor fabrication. This can include chemical vapor deposition (CVD) processes such as atmospheric pressure CVD (APCVD), low pressure CVD (LPCVD), plasma-enhanced CVD (PECVD), photochemical (ultraviolet) (LPCVD), vapor phase epitaxy (VPE), and metalorganic CVD (MOCVD). Additional non-CVD methods such as molecular beam epitaxy (MBE) are also acceptable.

The channel 110 comprises a semiconductor material such as an organic conjugated molecule(s). Such conjugated molecules are characterized in that they have overlapping π orbitals and that they can assume two or more resonant structures. The organic molecules may be cyclic or acyclic. Examples of conjugated organic materials include one or more of polyacetylene (cis or trans); polyphenylacetylene (cis or trans); polydiphenylacetylene; polyaniline; poly (p-phenylene vinylene); polythiophene; polyporphyrins; porphyrinic macrocycles, thiol derivatized polyporphyrins; polymetallocenes such as polyferrocenes, polyphthalocyanines; polyvinylenes; polystiroles; and the like. Additionally, the properties of the polymer can be modified by doping with a suitable dopant (e.g., salt).

The channel 110 can be formed by a number of suitable techniques, some of which are described supra. One suitable technique that can be utilized is a spin-on technique that involves depositing a mixture of the polymer/polymer precursor and a solvent, and then removing the solvent from the first source/drain 104. Another technique is chemical vapor deposition (CVD) optionally including a gas reaction, gas phase deposition, and the like. CVD includes low pressure chemical vapor deposition (LPCVD), plasma enhanced chemical vapor deposition (PECVD), and high density chemical vapor deposition (HDCVD). It is not typically necessary to functionalize one or more ends of the organic molecule in order to attach it to the first and second source/drains 104, 114.

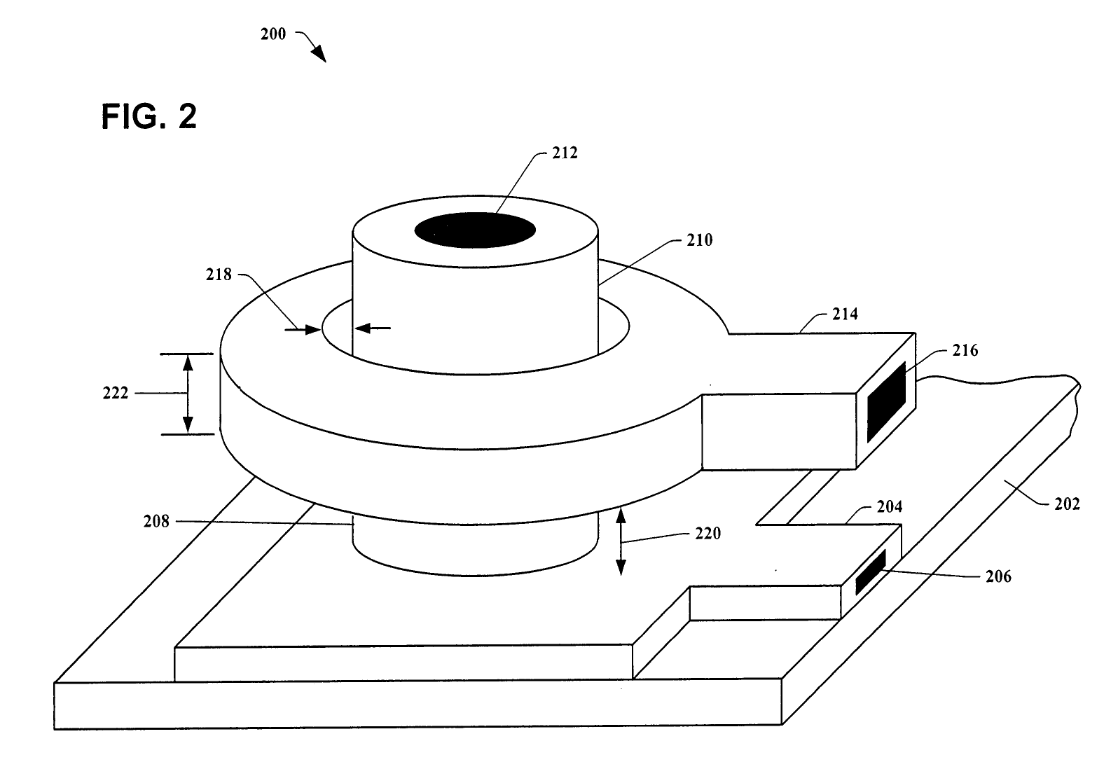

Turning to FIG. 2, a three dimensional view of a semiconductor device 200 illustrating a first and second source/drain 204, 210, a channel 208 and a gate 214 in accordance with an aspect of the present invention is depicted. In this view, all dielectric material is removed to better show the transistor components. The first source/drain 204 is formed on a substrate layer 202. It has a first contact point 206 or a via to allow for electrical connections. In this aspect of the present invention, the first contact point 206 is shown in a specific geometric shape and orientation. However, it can be a different shape and/or a different orientation and still be functional. The channel 208 is interposed between the first source/drain 204 and the second source/drain 210. It makes electrical contact with both the first and second source drains 204, 210. The second source/drain 210 has a second contact point 212 or a via to allow for electrical connections. In this aspect of the present invention, the second contact point 212 is shown in a specific geometric shape and orientation. However, it can be a different shape and/or a different orientation and still be functional. The annular gate 214 surrounds, at least in part, the channel 208 and the second source/drain 212. The annular gate 214 has a third contact point 216 or a via to allow for electrical connections. The orientation and shape of the third contact point 216 can differ from the illustration and still allow functional operation of the present invention. The orientation of the third contact point 216 does not need to be in any specific orientation with respect to the first contact point 206. The third contact point 216 can even be oriented vertically (upward, utilizing a 90 degree bend and the like) in the same plane as the second contact point 212. Likewise, the first contact point 206 can be routed to the same plane as the second contact point 212. Vias can also be utilized to reach the contact points 206, 212, 216 from any plane.

A gate-channel separation distance 218 defines a thickness for a gate oxide layer (not shown, see FIG. 1 and infra). Optimally, this approximate dimension is also utilized for a gate-first source/drain separation distance 220. An annular gate height 222 defines a gate width (due to the vertical, instead of horizontal, orientation of the device). The details of how the dimensions of the device interact are discussed infra.

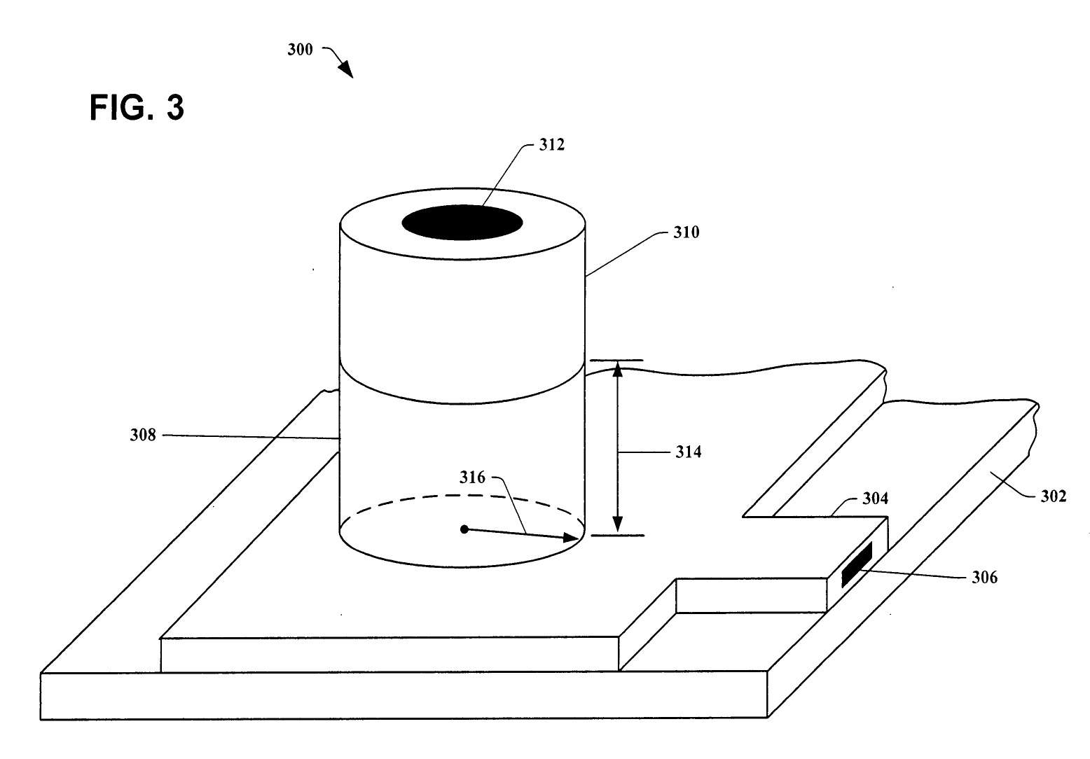

Moving on to FIG. 3, a three dimensional view of a semiconductor device 300 illustrating a first and second source/drain 304, 310 and a channel 308 in accordance with an aspect of the present invention is depicted. In this view, all dielectric material and the gate are removed to better show the remaining transistor components. The first source/drain 304 is formed on a substrate layer 302. It has a first contact point 306 or a via to allow for electrical connections. In this aspect of the present invention, the first contact point 306 is shown in a specific geometric shape and orientation. However, it can be a different shape and/or a different orientation and still be functional. The channel 308 is interposed between the first source/drain 304 and the second source/drain 310. It makes electrical contact with both the first and second source drains 304, 310. The second source/drain 310 has a second contact point 312 or a via to allow for electrical connections. In this aspect of the present invention, the second contact point 306 is shown in a specific geometric shape and orientation. However, it can be a different shape and/or a different orientation and still be functional. A channel height 314 defines a channel length for the device 300. This is due to the orientation, as shown, being in a vertical orientation instead of a typical horizontal orientation. The channel length defines the distance that current must flow between the first and second source/drains 304, 310. The importance of this dimension to the operation of a device is discussed in more detail infra.

In order to determine a width of the channel 308, it must be noted that the channel 308 is surrounded by an annular gate (not shown, see FIGS. 1 and 2). Therefore, the effective width of the gate is the circumference of the channel 308.

Basic geometry states:
circumference=2πR (Eq. 1)
where the approximate value of π is 3.14 . . . (the decimal continuing forever) and R is the radius of the circle (or, in this case, a channel radius 316 of the channel 308). Thus, the channel width is defined as:
channel width=2πR (Eq. 2)
In FIG. 3, the channel radius 316 of the channel 308 is depicted by an arrow. The importance of this dimension to the operation of a device is discussed in more detail infra.

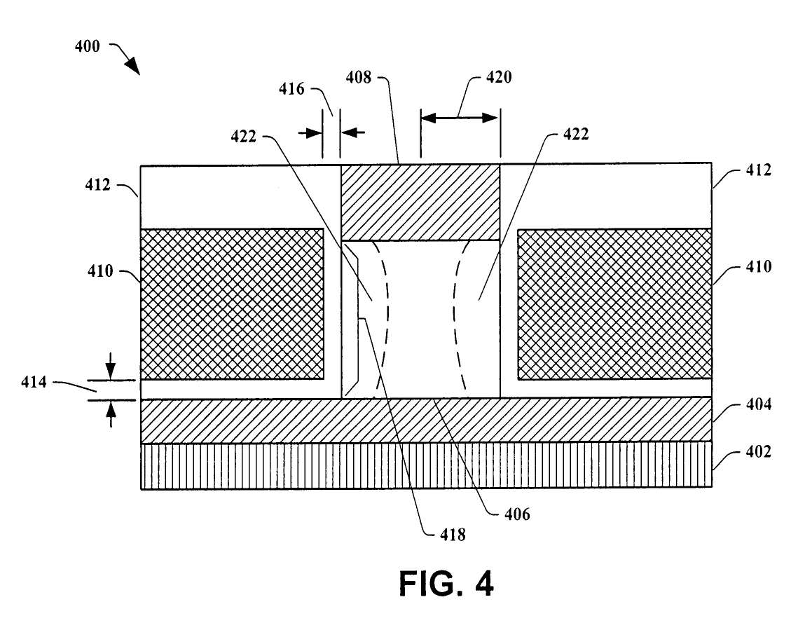

In FIG. 4, a cut-away diagram illustrating components and interfaces of a semiconductor device 400 in accordance with an aspect of the present invention is shown. The cut-away view allows a two dimensional view of the dimensions and relationships of the various components of one aspect of the present invention. A first source/drain layer 404 is formed on a substrate layer 402. A cylindrical channel 406 makes electrical contact with the first source/drain 404. It also makes electrical contact with a second source/drain 408. The channel 406 is interposed between the first and second source/drains 404, 408, allowing current to flow between the source/drains 404, 408 under proper conditions. An annular gate 410 appears as set of rectangles when dissected vertically. It lies in the proximity of the channel 406, enabling influence over the current flow through the channel 406. The gate 410 is separated from the channel 406 and the first and second source/drains 404, 408 by a dielectric material 412. Optimally, a gate-first source/drain separation dielectric material thickness 414 is approximately equal to a gate-channel separation dielectric material thickness 416. The gate-channel separation dielectric material thickness 416 is also known as a gate oxide layer. As noted supra, a channel width (due to it being surrounded by an annular gate) is denoted by 2πR where R is a radius 420 of the channel 406. Additionally, a height 418 of the channel 406 is the width of the channel 406 (due to the vertical versus horizontal orientation of the device 400).

Transistors can be PNP (n-doped sandwiched between p-doped regions) or NPN (p-doped sandwiched between n-doped regions) type depending on how they are manufactured and what materials are used. For a PNP transistor, current is carried by holes which are positively charged and are attracted by a negative voltage. For an NPN transistor, current is carried by electrons which are positively charged and are attracted by negative voltage. Generally speaking, the difference between the two types is the reversal of the potentials across the contacts. For this reason, a general discussion of only an NPN type transistor is given.

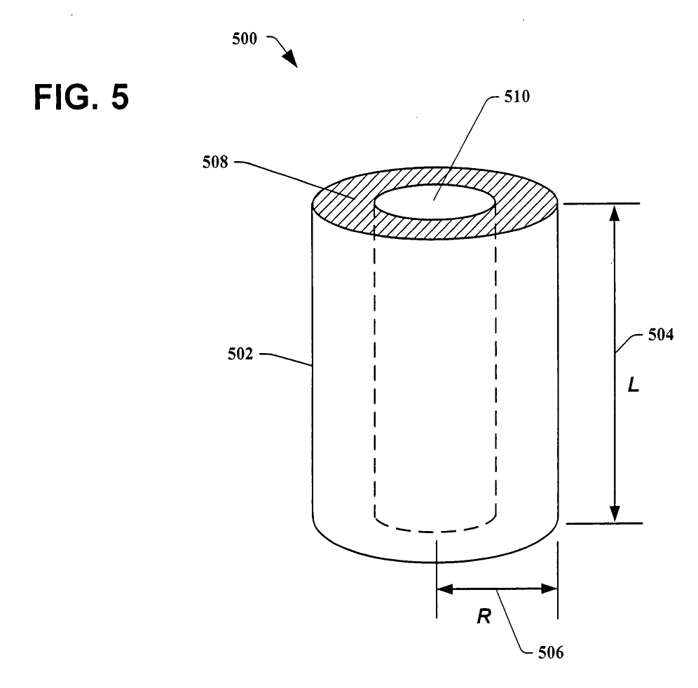

In a typical example of an NPN type transistor, a source and a drain are identical. However, the manner in which voltages are applied to a transistor's contacts determines which is the source and which is the drain. The source provides the electrons and the drain receives the electrons in this type of transistor. A voltage applied to the gate controls the flow of electrons from the source to the drain. The electrons form a conducting channel between the source and the drain which is known as an inversion layer 422. Because the present invention utilizes an annular gate, its inversion layer 422 is actually a tube-like structure (described infra in FIG. 5). The gate oxide prevents any current flow from the gate to the drain. Therefore, only a voltage applied to the gate is necessary to keep the electrons flowing.

Amplification is accomplished for both voltage and current. Current gain is achieved because no gate current is required to maintain the inversion layer 422 and the resulting current between the drain and the source. This allows the device to have infinite current gain in DC (direct current) applications. Due to the isolation of the gate from the channel, DC input impedance is also very high. This current gain is inversely proportional to its signal frequency. Voltage gain is caused by current saturation at higher drain/source voltages. This allows a small current variation to cause a large drain voltage variation.

Turning to FIG. 5, a three dimensional view of a channel 502 of a semiconductor device 500 in accordance with an aspect of the present invention is illustrated. This view depicts an inversion region 508 formed in the present invention. The channel 502 has a height 504, L, which equates to a channel length and a radius 506, R, used to calculate a channel width, W, of 2πR. When a voltage is applied to a gate of the present invention, the inversion region 508 and an unaffected region 510 is formed. Although the inversion region is depicted with parallel lines, the actual region width varies along the channel length, dependent upon the gate voltage. Current flows through the inversion region 508 between a first and second source/drain (not shown). Because the gate of the present invention surrounds the channel 502, the inversion region 508 is larger than a typical transistor, allowing greater current flow for a similar sized device.

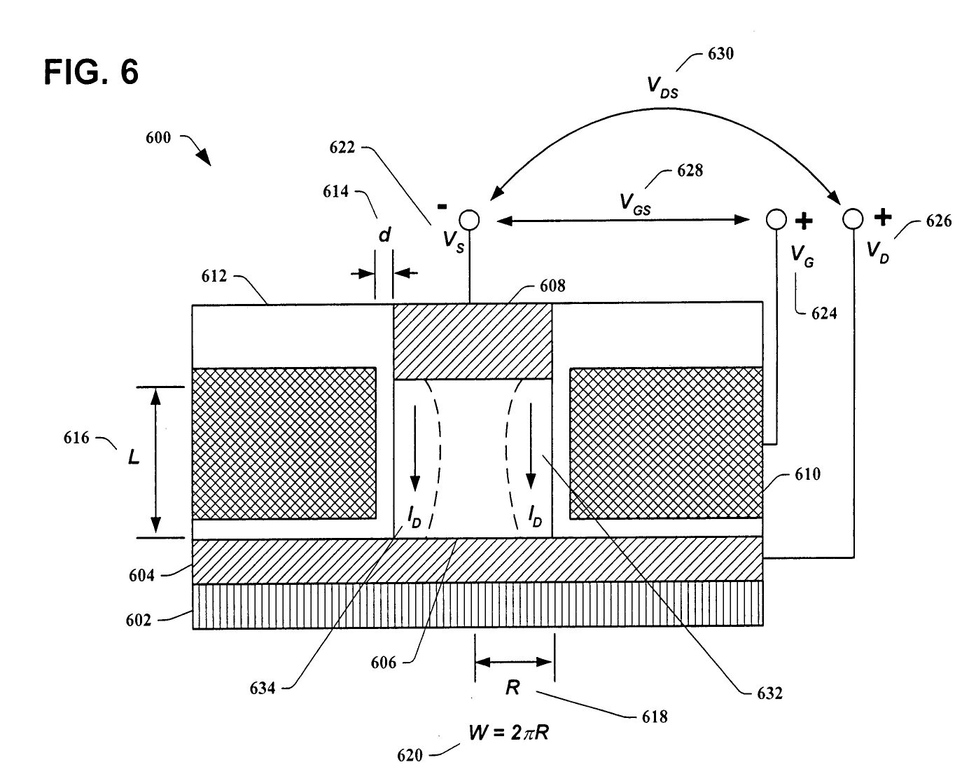

Moving on to FIG. 6, another cut-away diagram illustrating components, interfaces and electrical characteristics of a semiconductor device 600 in accordance with an aspect of the present invention is shown. A drain 604 is formed on a substrate material layer 602. A cylindrical channel 606 with charge carrier doping makes electrical contact with the drain 604. A source 608 also makes electrical contact with the cylindrical channel 606, opposite the drain 604. An annular gate 610 (shown as rectangles due to the cut-away view) surrounds the cylindrical channel 606. A dielectric material 612 separates the annular gate 610 from the cylindrical channel 606 and also from the drain 604. The dielectric material 612 has a thickness, d 614, between the annular gate 610 and the cylindrical channel 606. The dielectric material 612 located between the gate 610 and the cylindrical channel 606 is also known as a gate oxide (the dielectric material 612 is often an oxide material). The cylindrical channel 606 has a height which is actually the channel length, L 616, due to a vertical orientation instead of a horizontal orientation of the device 600. The cylindrical channel 606 has a radius, R 618, which is used to determine a channel width, W, based on the formula W=2πR 620.

In order to fully understand the operation of the present device, it is helpful to illustrate by example an instance of the present invention for an NPN configuration. A voltage level, V_{S} 622, represents a voltage level of the source 608. A voltage level, V_{G} 624, represents a voltage level of the annular gate 610. A voltage level, V_{D} 626, represents a voltage level of the drain 604. A potential difference between the source 608 and the annular gate 610 is represented by V_{GS} 628. A potential difference between the source 608 and the drain 604 is represented by V_{DS} 630. Since the cylindrical channel 606 is doped, an inversion region 632 is formed within the cylindrical channel 606. A current, I_{D} 634, can flow through the inversion region 632 under certain conditions. The annular gate 610 controls the current, I_{D} 634, by varying the conductance of the inversion region 632 in the cylindrical channel 606. Varying ranges of conductivity can be achieved with the present invention by utilizing different polymers and/or different doping levels. For a given V_{GS} 628, there exists a V_{DS} 630 where I_{D} 634 becomes saturated and can no longer increase.

Threshold voltages play an important part in determining what region a transistor is operating in. A threshold voltage, V_{T}, is a minimum gate voltage, V_{G} 624, required to induce a current, I_{D} 634, in the cylindrical channel 606. Therefore, V_{GS} 628 must be greater than V_{T} for an inversion region 632 to form. Generally speaking, a transistor can operate in different modes such as enhancement mode or depletion mode. Enhancement mode is defined when a transistor is OFF at the same time that V_{GS} 628 is zero and, subsequently, a positive VG 624 is required to create an inversion region 632 in the cylindrical channel 606. This mode, due to its characteristics, can be employed in digital circuitry that requires switching between ON and OFF states. Depletion mode is defined when the cylindrical channel 606 has an existing inversion region 632 when V_{GS} 628 is equal to zero. In this mode, the device 600 operates with both positive and negative levels of V_{GS} 628.

The most common operating mode is the enhancement mode. Its drain characteristics are discussed with reference to FIG. 6. For a given instance of the present invention, the following formulations determine the characteristics of the device 600. When V_{DS} 630 is equal to zero and V_{GS} 628 is greater than V_{T}, an electric charge per unit length, Q(x), (where x represents distance) is induced along the inversion region 632 as follows:
Q(x)=−C*W*(V_{GS}−V_{T}) (Eq. 3)
where C is the capacitance per unit length for a parallel plate capacitor. The capacitance can also be written as:
C=(Ε_{S}*ε_{O})/d (Eq. 4)
where, ε₀, is the permittivity in a vacuum (8.85418*10⁻¹⁴ F/cm) and, ε_{S}, is the permittivity of a given semiconductor material (F/cm). The electric field between the theoretical plates of the capacitor terminates at the negative charges in the cylindrical channel 606 just beyond the dielectric material layer 612 between the annular gate 610 and the cylindrical channel 606. As long as V_{DS} 630 is greater than zero, the voltage across the inversion region 632 increases with the distance from the source 608. Therefore, the voltage at any point along the annular gate 610 can be given as V(x), where x represents the distance from the source 608. It follows that the charge, Q(x), can be rewritten as a function of distance:
Q(x)=−C*W*[V_{GS}−V_{T}V(x)] (Eq. 5)
Given the drain current, I_{D}, is:
I_{D}=σ*E*A (Eq. 6)
where, E, is the electric field, A, is the cross sectional area of the channel 606, σ, is the conductivity defined as:
σ=n*q*μ (Eq. 7)
and where, μ, is the electron mobility of a given material and, q, is the elementary charge value of 1.60218*10⁻¹⁹ Coulombs. Given the following two equations:
n*q=−Q(x)/A (Eq. 8)
E=dV(x)/dx (Eq. 9)
The current, I_{D}, can be rewritten as:
I_{D}=[μ*C*W[V_{GS}−V_{T}−V(x)]]dV(x)/dx (Eq. 10)
The inversion region 632 is present when V_{GS}−V_{DS} is greater than or equal to V_{T}. Integrating Eq. 10 over the length, L, for I_{D} and from 0 to V_{DS} for the right hand side of Eq. 10 gives:
I_{D}=(μ*C*)/(2*L)*[2*(V_{GS}−V_{T})*V_{DS}−V_{DS}²] (Eq. 11)
Pinch off and saturation occurs when V_{GS}−V_{DS} is equal to V_{T} and the boundary is defined by:
I_{D}=(μ*C*W)/(2*L)*V_{DS} (Eq. 12)
and in the saturation region V_{DS} is greater than V_{GS}−V_{T}, therefore:
I_{D}=(μ*C*W)/(2*L)*(V_{GS}−V_{T})=k*(V_{GS}−V_{T}) (Eq. 13)
Therefore, for the present invention:
k=(μ*C*2πR)/(2*L)=(μ*C*πR)/L (Eq. 14)

Thus, for an instance of the present invention with a given V_{T}, the current, I_{D} 634, can be increased by, increasing the radius, R 618, of the cylindrical channel 606 of the device 600. The current, I_{D} 634, can also be increased by decreasing the length, L 616. The mobility, μ, can also be increased to increase the current, I_{D} 634, by utilizing doped polymers with higher mobility values. Increasing the capacitance, C, can also increase the current, I_{D} 634, by decreasing the theoretical plate distance, d, and/or selecting semiconductor material with a higher permittivity value.

One skilled in the art can appreciate that any system with a means to utilize an annular gate to control current through a polymer-based material falls within the scope of the present invention. That is, any system that employs a 360 degree element emanating an electrical field to create an inversion layer in a polymer-based device is an aspect of the present invention. Thus, the geometric shape of the device can vary and still be covered by the present invention scope. In the same light, the material composition of the elements of the device can also vary.

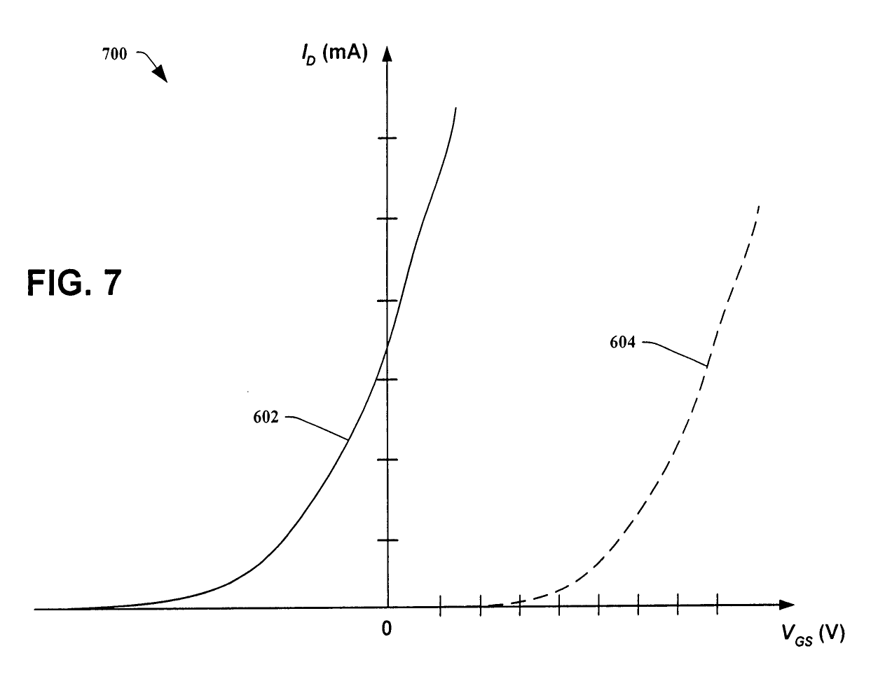

Referring to FIG. 7, a graph 700 illustrating different modal operating characteristics of a semiconductor device in accordance with an aspect of the present invention are depicted. The axes of the graph plot the current, I_{D}, versus the voltage, V_{GS}, for depletion mode operation 602 and for enhanced mode operation 604. From the graph 700 it is readily apparent that the depletion mode operation 602 can function with positive or negative values of V_{GS}. Also, note that when V_{GS} is equal to zero, I_{D} is not equal to zero. For enhanced mode operation 604, I_{D} is equal to zero when V_{GS} is equal to zero. Thus, the enhanced mode operation has the capability to switch currents ON and OFF. This is extremely useful in digital switching circuitry and in controlling memory devices.

The present invention semiconductor devices are useful in any device requiring amplification of a signal and/or control of current. For example, the semiconductor devices of the present invention are useful in memory, computers, appliances, industrial equipment, hand-held devices, telecommunications equipment, medical equipment, research and development equipment, transportation vehicles, radar/satellite devices, and the like. Hand-held devices, and particularly hand-held electronic devices, achieve improvements in portability due to the small size and light weight of the polymer-based semiconductor devices. Examples of hand-held devices include cell phones and other two way communication devices, personal data assistants, palm pilots, pagers, notebook computers, remote controls, recorders (video and audio), radios, small televisions and web viewers, cameras, and the like.

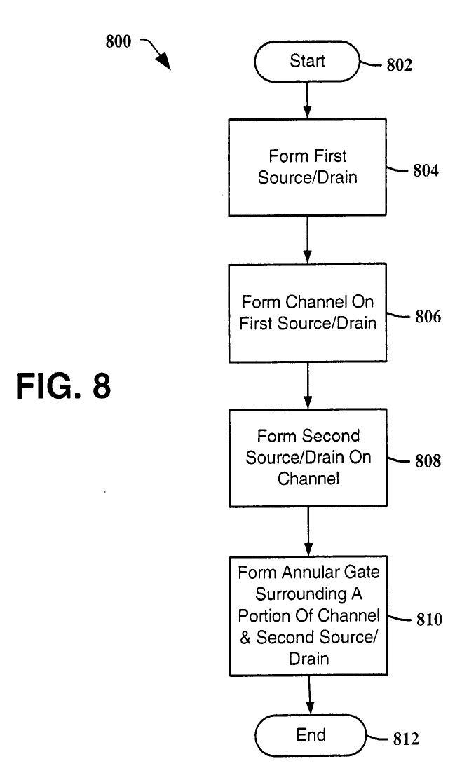

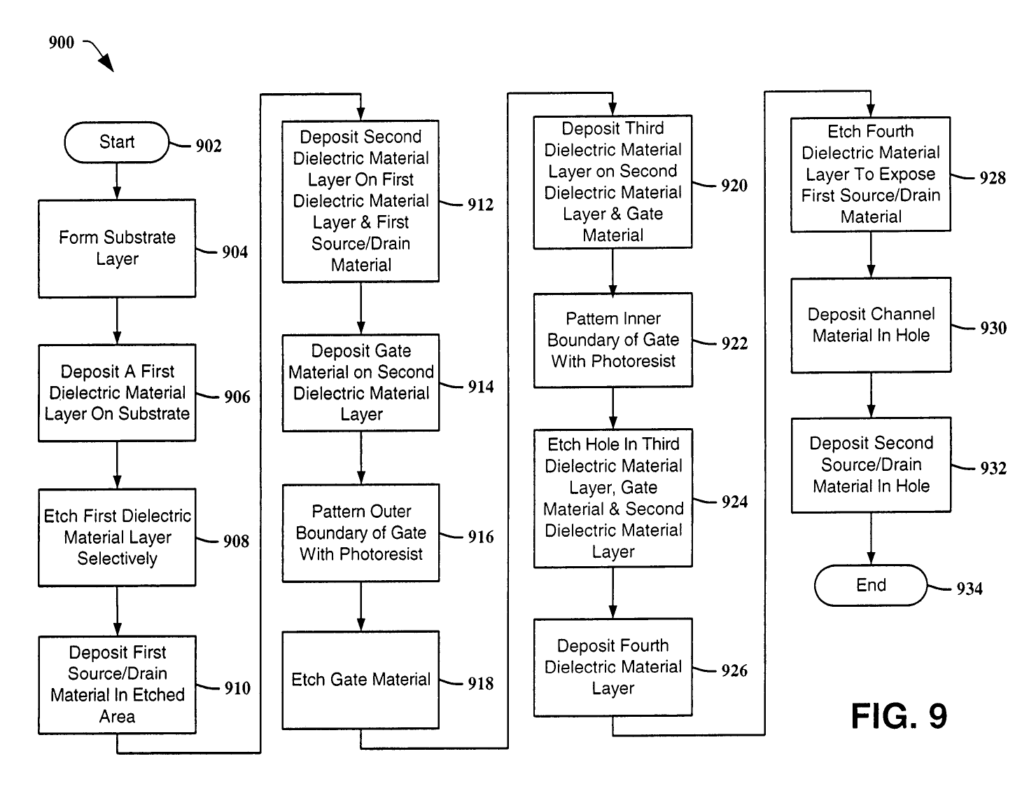

In view of the exemplary systems shown and described above, methodologies, which may be implemented in accordance with one or more aspects of the present invention, will be better appreciated with reference to the flow diagrams of FIGS. 8 and 9. While, for purposes of simplicity of explanation, the methodology may be shown and described as a series of function blocks. However, it is to be understood and appreciated that the present invention is not limited by the order of the blocks, as some blocks may, in accordance with the present invention, occur in different orders and/or concurrently with other blocks from that shown and described herein.

Moreover, not all illustrated blocks may be required to implement a methodology in accordance with one or more aspects of the present invention. It is to be appreciated that the various blocks may be implemented via software, hardware a combination thereof or any other suitable means (e.g. device, system, process, component) for carrying out the functionality associated with the blocks. It is also to be appreciated that the blocks are merely to illustrate certain aspects of the present invention in a simplified form and that these aspects may be illustrated via a lesser and/or greater number of blocks.

In FIG. 8, a flow diagram illustrating a method 800 of fabricating a semiconductor device in accordance with an aspect of the present invention is depicted. The process starts 802 by forming a first source/drain 804. The material utilized for the first source/drain is generally a conductive material such as aluminum, chromium, copper, germanium, gold, magnesium, manganese, indium, iron, nickel, palladium, platinum, silver, titanium, zinc, alloys thereof, indium-tin oxide, polysilicon, doped amorphous silicon, metal silicides, and the like. Exemplary alloys that can be utilized for the conductive material include Hastelloy®, Kovar®, Invar, Monel®, Inconel®, brass, stainless steel, magnesium-silver alloy, and various other alloys. The thickness of the first source/drain can vary depending on the implementation and the desired characteristics of the semiconductor device being constructed. However, some exemplary thickness ranges include about 0.01 μm or more and about 10 μm or less, about 0.05 μm or more and about 5 μm or less, and/or about 0.1 μm or more and about 1 μm or less.

The first source/drain can be deposited on a substrate in any manner suitable for transistor fabrication. This can include chemical vapor deposition (CVD) processes such as atmospheric pressure CVD (APCVD), low pressure CVD (LPCVD), plasma-enhanced CVD (PECVD), photochemical (ultraviolet) (LPCVD), vapor phase epitaxy (VPE), and metalorganic CVD (MOCVD). Additional non-CVD methods such as molecular beam epitaxy (MBE) are also acceptable.

A channel is then formed on the first source/drain 806. The channel is generally composed of a semiconductor material, such as an organic conjugated molecule(s), that can be doped to allow current control through the material. Such conjugated molecules are characterized in that they have overlapping π orbitals and that they can assume two or more resonant structures. The organic molecules may be cyclic or acyclic. Examples of conjugated organic materials include one or more of polyacetylene (cis or trans); polyphenylacetylene (cis or trans); polydiphenylacetylene; polyaniline; poly (p-phenylene vinylene); polythiophene; polyporphyrins; porphyrinic macrocycles, thiol derivatized polyporphyrins; polymetallocenes such as polyferrocenes, polyphthalocyanines; polyvinylenes; polystiroles; and the like. Additionally, the properties of the polymer can be modified by doping with a suitable dopant (e.g., salt).

The channel can be formed by a number of suitable techniques, some of which are described supra. One suitable technique that can be utilized is a spin-on technique that involves depositing a mixture of the polymer/polymer precursor and a solvent, and then removing the solvent from the first source/drain. Another technique is chemical vapor deposition (CVD) optionally including a gas reaction, gas phase deposition, and the like. CVD includes low pressure chemical vapor deposition (LPCVD), plasma enhanced chemical vapor deposition (PECVD), and high density chemical vapor deposition (HDCVD). It is not typically necessary to functionalize one or more ends of the organic molecule in order to attach it to the first source/drain.

A second source/drain is formed on the channel 808. The second source/drain is a conductive material, such as listed supra for the first source/drain, and may or may not be composed of the same material as the first source/drain. The second source/drain can be deposited on the channel employing the same methods as for the first source/drain listed supra. An annular gate is then formed such that it surrounds at least a portion of the channel and the second source/drain 810, ending the flow 812. The annular gate is generally composed of conductive material capable of producing a current controlling field in the channel such as polycrystalline silicon and the like. Similar methods as listed supra can be utilized for the formation of the gate.

Referring to FIG. 9, another flow diagram illustrating a method 900 of fabricating a semiconductor device in accordance with an aspect of the present invention is shown. The process starts 902 by forming a substrate layer 904. This layer is generally composed of a dielectric material such as silicon dioxide (SiO₂) and is formed with any method appropriate for the type of device being fabricated. A first dielectric material layer is then deposited on the substrate layer 906. The dielectric material layer is frequently composed of an oxide and can be deposited on a substrate in any manner suitable for transistor fabrication. This can include chemical vapor deposition (CVD) processes such as atmospheric pressure CVD (APCVD), low pressure CVD (LPCVD), plasma-enhanced CVD (PECVD), photochemical (ultraviolet) (LPCVD), vapor phase epitaxy (VPE), and metalorganic CVD (MOCVD). Additional non-CVD methods such as molecular beam epitaxy (MBE) are also acceptable.

The first dielectric material layer is etched selectively 908 to allow a first source/drain to contact the substrate layer. A first source/drain material is deposited in the etched area 910. The first source/drain can be deposited on a substrate in any manner suitable for transistor fabrication. This can include chemical vapor deposition (CVD) processes such as atmospheric pressure CVD (APCVD), low pressure CVD (LPCVD), plasma-enhanced CVD (PECVD), photochemical (ultraviolet) (LPCVD), vapor phase epitaxy (VPE), and metalorganic CVD (MOCVD). Additional non-CVD methods such as molecular beam epitaxy (MBE) are also acceptable.

A second dielectric material layer is then deposited on the first dielectric material layer and the first source/drain material 912. This layer provides isolation of a first source/drain from a gate and is typically a thin layer. This layer can be deposited by the deposition methods stated supra for the first dielectric layer. Gate material is then deposited on the second dielectric material layer 914. The gate material can be deposited utilizing the methods stated supra for the first source/drain deposition. An outer boundary of a gate is patterned on the gate material with photoresist 916. The gate material is then etched 918 to form the outer boundary.

A third dielectric material layer is deposited on the second dielectric material layer and the gate material 920. This layer can be deposited by the deposition methods utilized supra for the previous dielectric material layers. An inner boundary of the gate is patterned on the third dielectric material layer with photoresist 922. A hole is then etched through the third dielectric material layer, the gate material and the second dielectric material layer 924, exposing the first source drain.

A fourth dielectric material layer is then deposited 926 over the exposed surfaces of the first source/drain, a portion of the second dielectric material layer, the gate material, and the third dielectric material layer. This layer provides isolation of a gate from a channel and is typically a thin layer. This layer can be deposited by the deposition methods utilized supra for the previous dielectric material layers. The fourth dielectric material layer is then etched to expose the first source drain material 928. This allows a channel to have electrical contact with a first source/drain. Channel material is then deposited in the hole 930.

The channel material typically does not completely fill the hole, allowing a second source/drain to be formed. The channel is generally composed of a semiconductor material, such as an organic conjugated molecule(s), that can be doped to allow current control through the material. Such conjugated molecules are characterized in that they have overlapping 7 orbitals and that they can assume two or more resonant structures. The organic molecules may be cyclic or acyclic. Examples of conjugated organic materials include one or more of polyacetylene (cis or trans); polyphenylacetylene (cis or trans); polydiphenylacetylene; polyaniline; poly (p-phenylene vinylene); polythiophene; polyporphyrins; porphyrinic macrocycles, thiol derivatized polyporphyrins; polymetallocenes such as polyferrocenes, polyphthalocyanines; polyvinylenes; polystiroles; and the like. Additionally, the properties of the polymer can be modified by doping with a suitable dopant (e.g., salt).

The channel can be formed by a number of suitable techniques, some of which are described supra. One suitable technique that can be utilized is a spin-on technique that involves depositing a mixture of the polymer/polymer precursor and a solvent, and then removing the solvent from the first source/drain. Another technique is chemical vapor deposition (CVD) optionally including a gas reaction, gas phase deposition, and the like. CVD includes low pressure chemical vapor deposition (LPCVD), plasma enhanced chemical vapor deposition (PECVD), and high density chemical vapor deposition (HDCVD). It is not typically necessary to functionalize one or more ends of the organic molecule in order to attach it to the first source/drain.

A second source/drain material is deposited in the hole 932 over the channel material, ending the flow 934. This allows for electrical contact between a second source/drain and a channel. The second source/drain material is comprised of similar conductive materials as listed for the first source/drain supra. Both source/drains can be made of the same material but do not have to be the same material. Deposition of the second source/drain material can utilize the same techniques as described for the first source/drain listed supra.

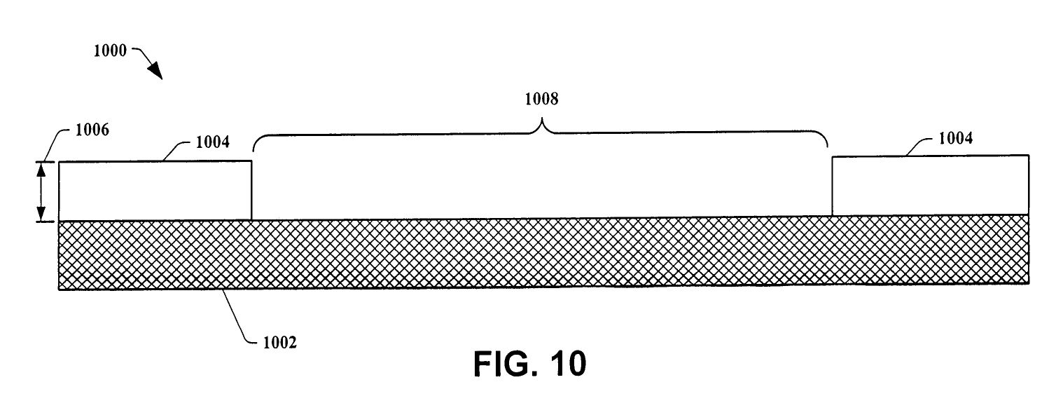

Turning to FIG. 10, a diagram 1000 illustrating fabrication of a substrate layer 1002 and a first dielectric layer 1004 for a semiconductor device in accordance with an aspect of the present invention is shown. The first dielectric material layer 1004 is deposited on the substrate layer 1002 and etched to form an area 1008 where a first source/drain can be formed. A thickness 1006 of this layer 1004 approximates a desired thickness of a first source/drain. The substrate layer is typically silicon dioxide (SiO₂) and the like. The first dielectric material layer 1004 is typically comprised of an oxide material. This layer 1004 provides electrical isolation for a first source/drain (not shown).

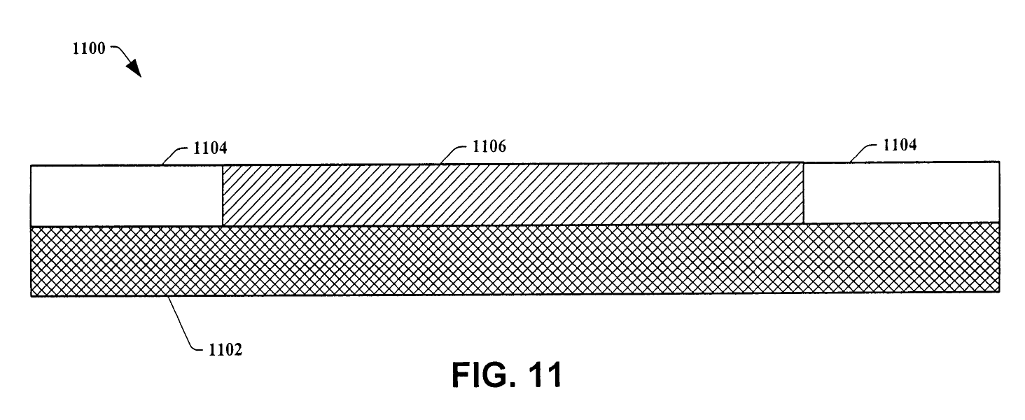

In FIG. 11, a diagram 1100 illustrating fabrication of a first source/drain for a semiconductor device in accordance with an aspect of the present invention is illustrated. A first source/drain material 1104 is deposited on a substrate layer 1104 left exposed by etching of a dielectric material layer 1104. The process typically yields a roughened surface and it is polished after the deposition of the first source/drain material 1104.

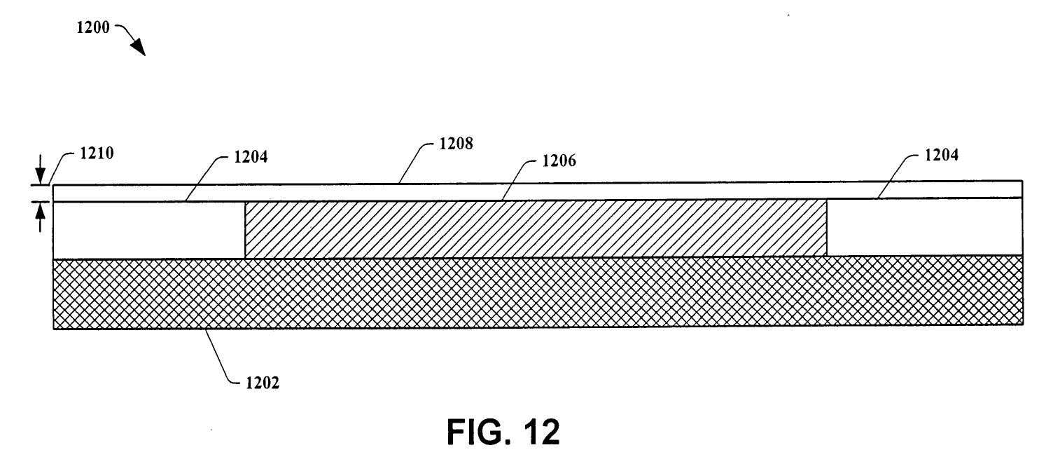

Looking at FIG. 12, a diagram 1200 illustrating fabrication of a second dielectric material layer for a semiconductor device in accordance with an aspect of the present invention is depicted. A first source/drain 1206 is formed on a substrate layer 1202. The first source/drain 1206 is isolated on its sides by a first layer of etched dielectric material 1204. A second dielectric material layer 1208 is formed over the first dielectric layer 1204 and the first source/drain 1206. The second dielectric material layer 1208 is generally composed of an oxide. A thickness 1210 of this layer 1208 is approximately equal to a gate oxide layer thickness.

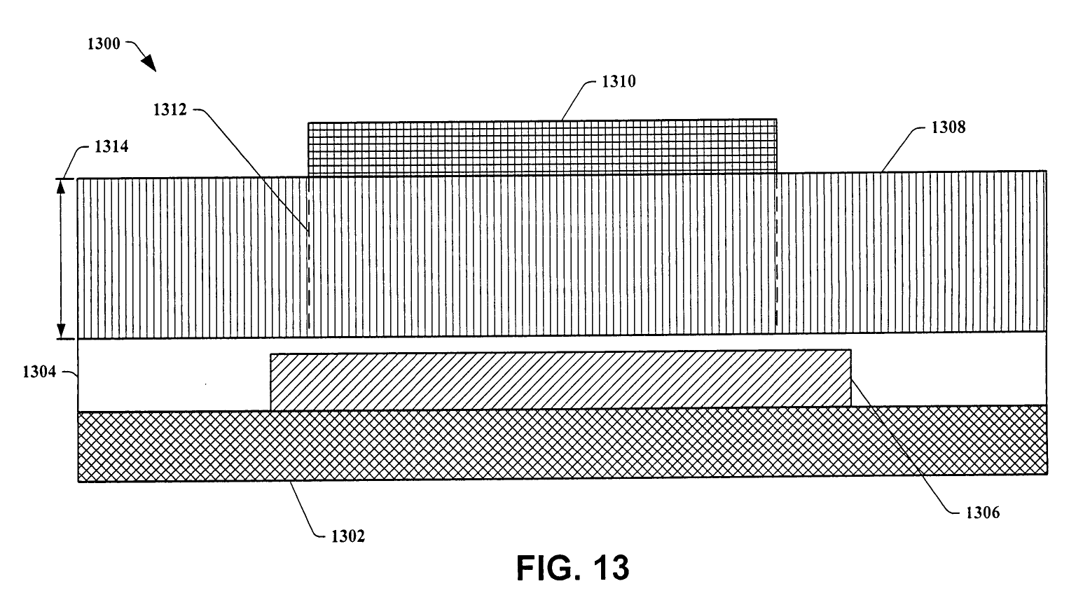

Moving on to FIG. 13, a diagram 1300 illustrating fabrication of a gate material layer 1308 for a semiconductor device in accordance with an aspect of the present invention is illustrated. The gate material layer 1308 is formed on dielectric material layer 1304 which lies over a first source/drain 1306 and a substrate layer 1302. A thickness 1314 of this layer 1308 determines the height of an annular gate. The gate material layer 1308 is typically polysilicon and the like. A photoresist pattern 1310 is used to determine the outer boundary 1312 of the annular gate.

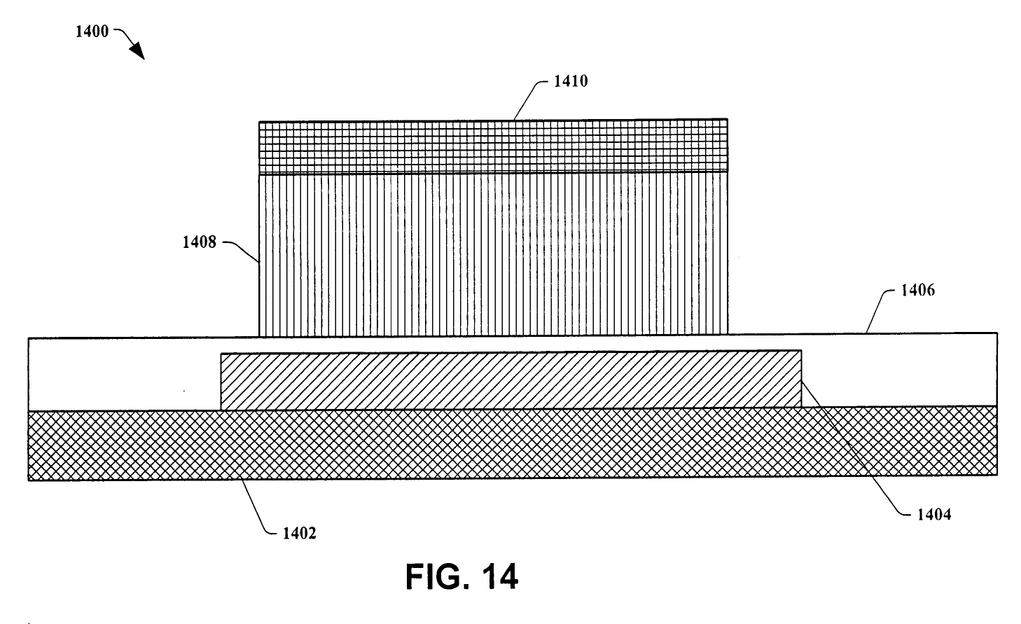

Turning to FIG. 14, a diagram 1400 illustrating fabrication of a gate for a semiconductor device in accordance with an aspect of the present invention is shown. A gate material layer 1408 formed on a dielectric material layer 1406 is etched utilizing a photoresist pattern 1410. The etching removes the gate material layer portion not protected by the photoresist pattern 1410 down to the dielectric material layer 1406. This forms an outer boundary limit of a gate. The dielectric material layer 1406 insulates a first source/drain 1404 from the gate material layer 1408. A substrate layer 1402 supports both the dielectric material layer 1406 and the first source/drain 1404.

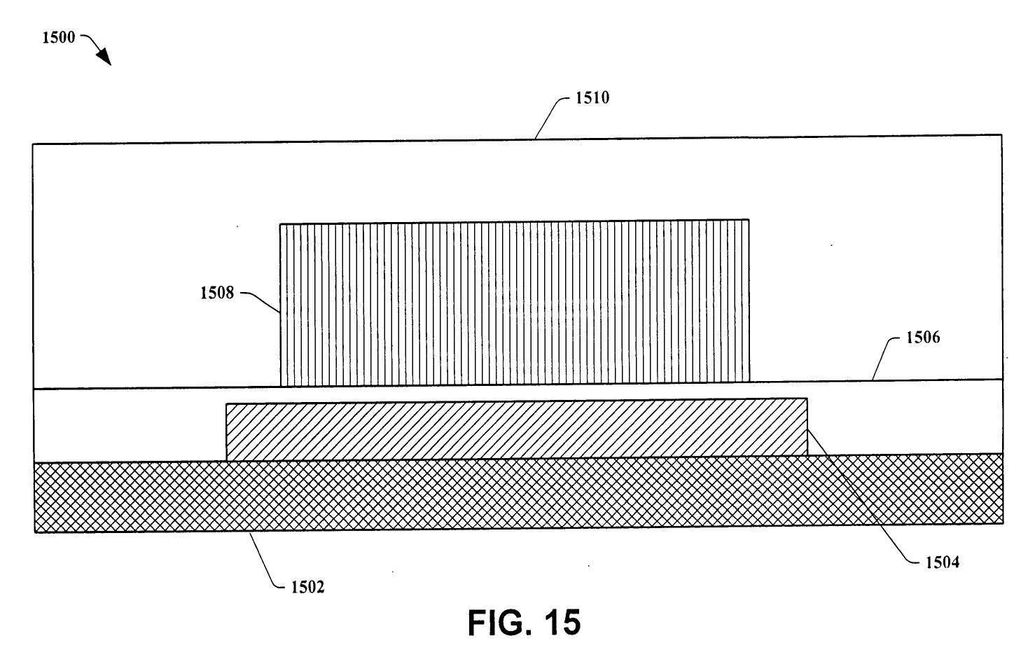

In FIG. 15, another diagram 1500 illustrating fabrication of a dielectric material layer 1510 for a semiconductor device in accordance with an aspect of the present invention is illustrated. The dielectric material layer 1510 is formed over an etched gate material layer 1508 and another previously formed dielectric material layer 1506. This layer 1510 insulates a gate from external electrical contact and provides a means to create an inner hole for the gate. The previously formed dielectric material layer 1506 isolates a first source/drain 1504 from a gate and also protects a substrate layer 1502. The dielectric material layer 1510 can be comprised of silicon dioxide (SiO₂) and the like.

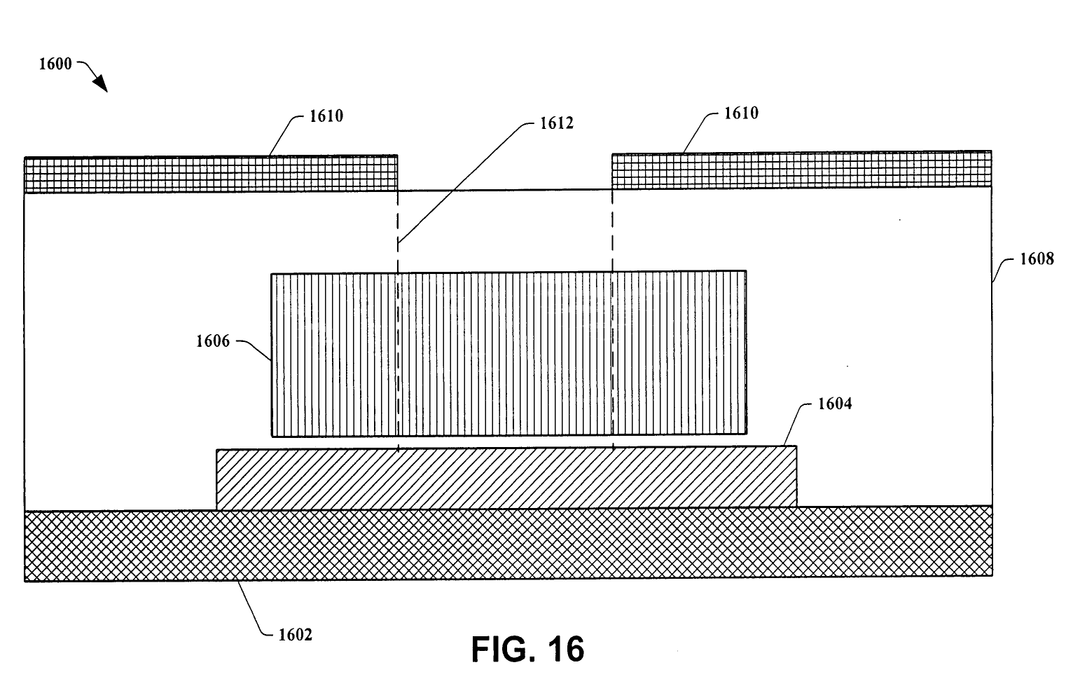

Referring to FIG. 16, a diagram 1600 illustrating patterning of an inner gate region for a semiconductor device in accordance with an aspect of the present invention is shown. A photoresist pattern 1610 is formed on a dielectric material layer 1608 to create an inner boundary 1612 of a gate. The photoresist pattern 1610 allows creation of a hole that penetrates through the dielectric material layer 1608 and a gate material layer 1606 down to a first source/drain 1604. This allows for formation of a gate oxide layer and a contact area for a channel with the first source/drain 1604. A substrate layer 1602 supports the dielectric material layer 1608 and the first source/drain 1604.

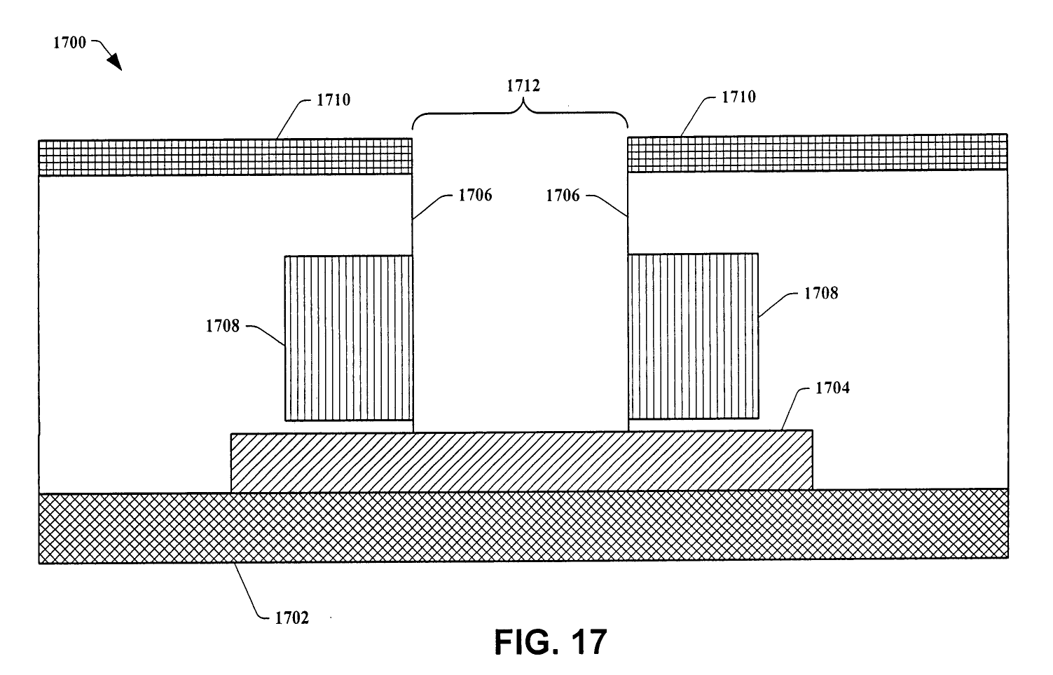

Looking at FIG. 17, a diagram 1700 illustrating fabrication of an inner gate region 1712 for a semiconductor device in accordance with an aspect of the present invention is depicted. A photoresist pattern 1710 is used to form the inner gate region 1712. An etch process, such as an anisotropic etch and the like, is used to create the inner gate region 1712. The inner gate region 1712 extends through a dielectric material layer 1706 and a gate material layer 1708, exposing a first source/drain 1704. A substrate layer 1702 supports the first source/drain layer 1704 and the dielectric material layer 1706.

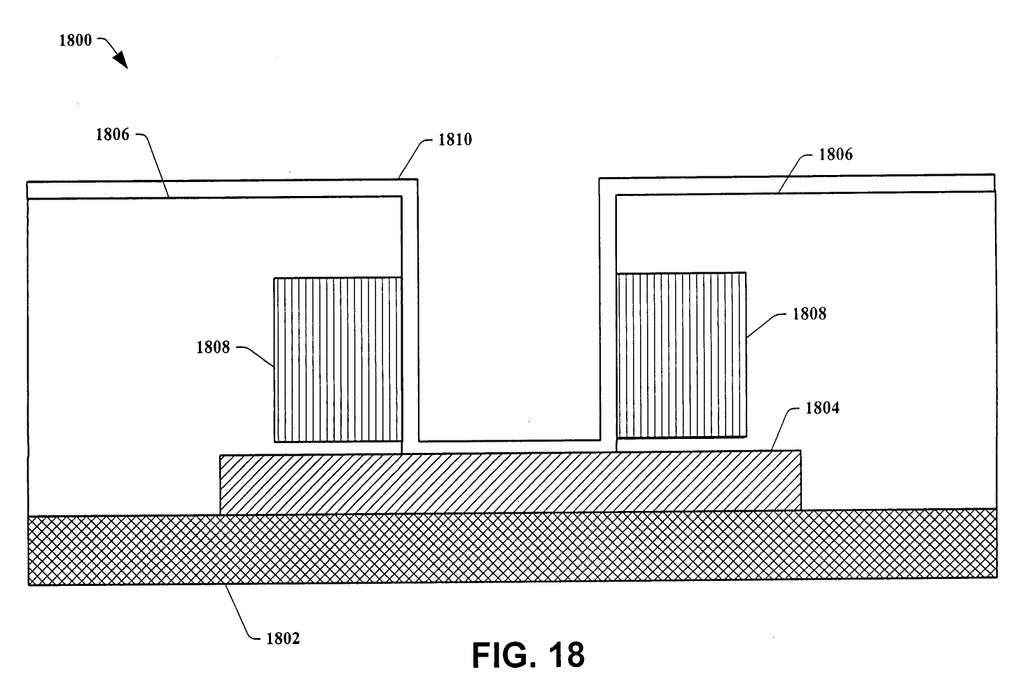

Turning to FIG. 18, yet another diagram 1800 illustrating fabrication of a dielectric material layer 1810 for a semiconductor device in accordance with an aspect of the present invention is shown. The dielectric material layer 1810 is formed over a previously deposited etched dielectric material layer 1806, an etched gate material layer 1808, and a first source/drain 1804. Generally, this dielectric material layer 1810 is thin and provides electrical insulation between a gate, a channel and a second source/drain. Often this dielectric material layer 1810 is comprised of an oxide. Thus, part of its function is to provide a gate oxide layer between the gate and the channel. A substrate 1802 provides support for the first source/drain 1804 and the previously deposited dielectric material 1806.

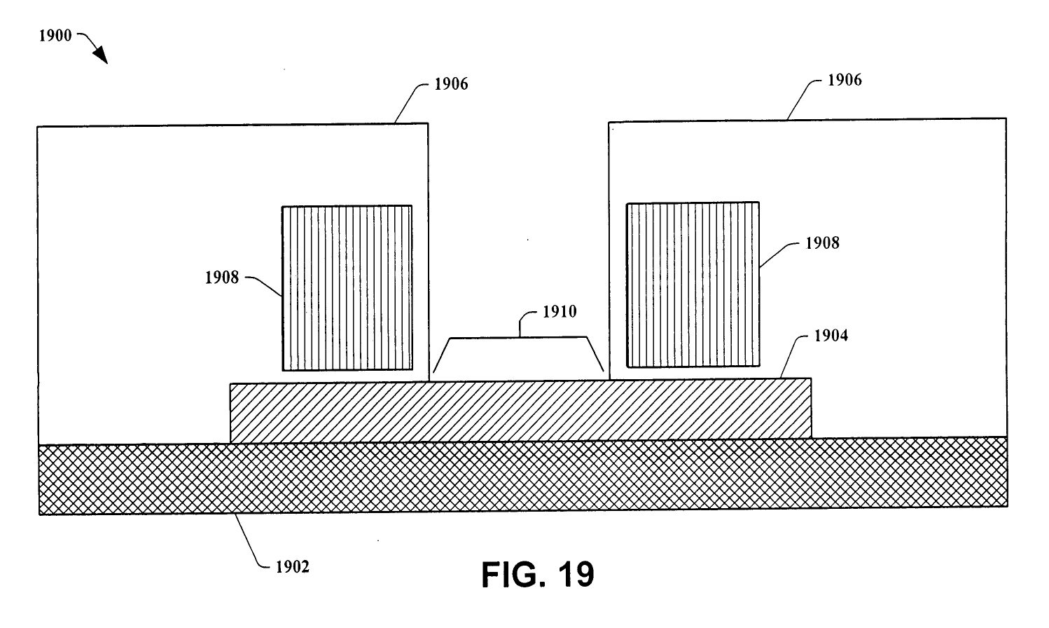

In FIG. 19, a diagram 1900 illustrating fabrication of a first source/drain contact region 1910 for a semiconductor device in accordance with an aspect of the present invention is illustrated. An etching process, such as anisotropic etching and the like, is employed on a dielectric material layer 1906 to remove any remaining dielectric material from a first source/drain 1904, creating the first source/drain contact region 1910. This allows the first source/drain 1904 to electrically contact a channel (not shown) while still being isolated from a gate 1908. A substrate layer 1902 supports the first source/drain 1904 and the dielectric material layer 1906.

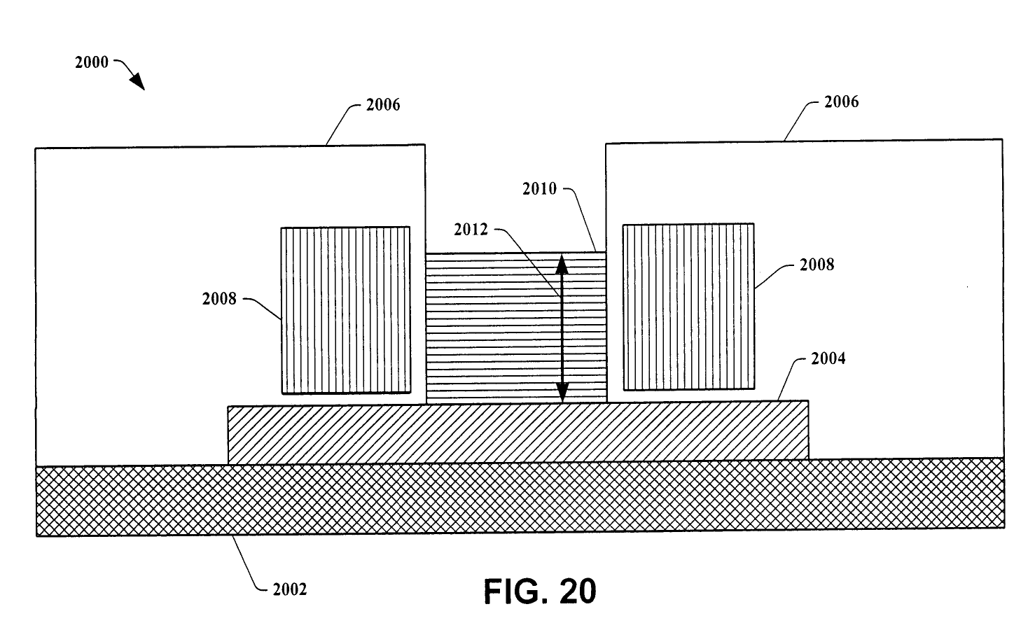

Referring to FIG. 20, a diagram 2000 illustrating fabrication of a channel for a semiconductor device in accordance with an aspect of the present invention is shown. A channel material 2010 is deposited on a first source/drain 2004. The channel material 2010 is electrically connected to the first source/drain 2004 but insulated by a dielectric material layer 2006 from a gate 2008. The process by which the channel material 2010 is deposited can be chemical-vapor deposition and the like. The channel material 2010 can be a conjugated polymer that is doped with charge carriers. The amount and type of doping is dependent upon the type of semiconductor device being manufactured (n-type doping versus p-type doping, etc.). The channel material 2006 forms a channel which can be controlled by the gate 2008 to regulate current flow from a second source/drain (not shown) to the first source/drain 2004. A thickness 2012 of the channel material 2010 determines a channel's length (due to the orientation being vertical instead of horizontal). And a circumference of the channel material 2010 determines a channel's width. Thus, these two parameters can be varied during manufacture to produce a semiconductor device with appropriate characteristics. A substrate layer 2002 provides support for the first source/drain 2004 and the dielectric material layer 2006.

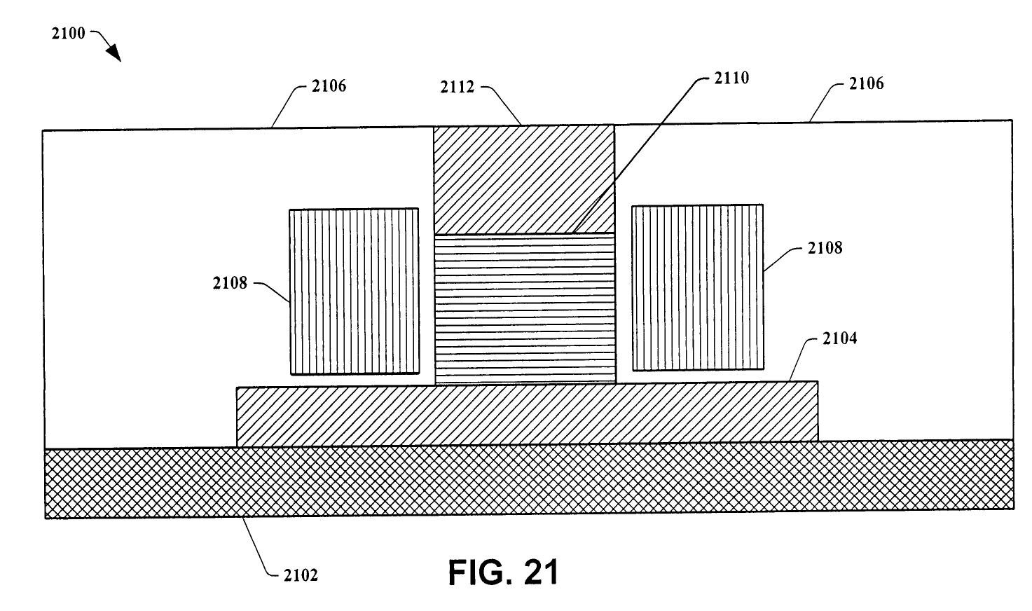

Looking at FIG. 21, a diagram 2100 illustrating fabrication of a second source/drain 2112 for a semiconductor device in accordance with an aspect of the present invention is illustrated. The second source/drain 2112 is formed by depositing a conductive material on a channel 2110. The second source/drain 2112 is electrically connected to the channel 2110 but isolated from a gate 2108 by a dielectric material 2106. The gate 2108 controls a current flowing between the second source/drain 2112 and a first source drain 2104. It does this via an electric field that penetrates the dielectric material 2106 and radiates into the channel 2110, creating an inversion layer which flows current. The semiconductor device is supported by a substrate layer 2102. During the manufacturing process, vias can be created for the gate 2108, the first source/drain 2104 and the second source/drain 2112. The vias allow electrical contacts to be made to each of these components even if the components are not readily exposed.

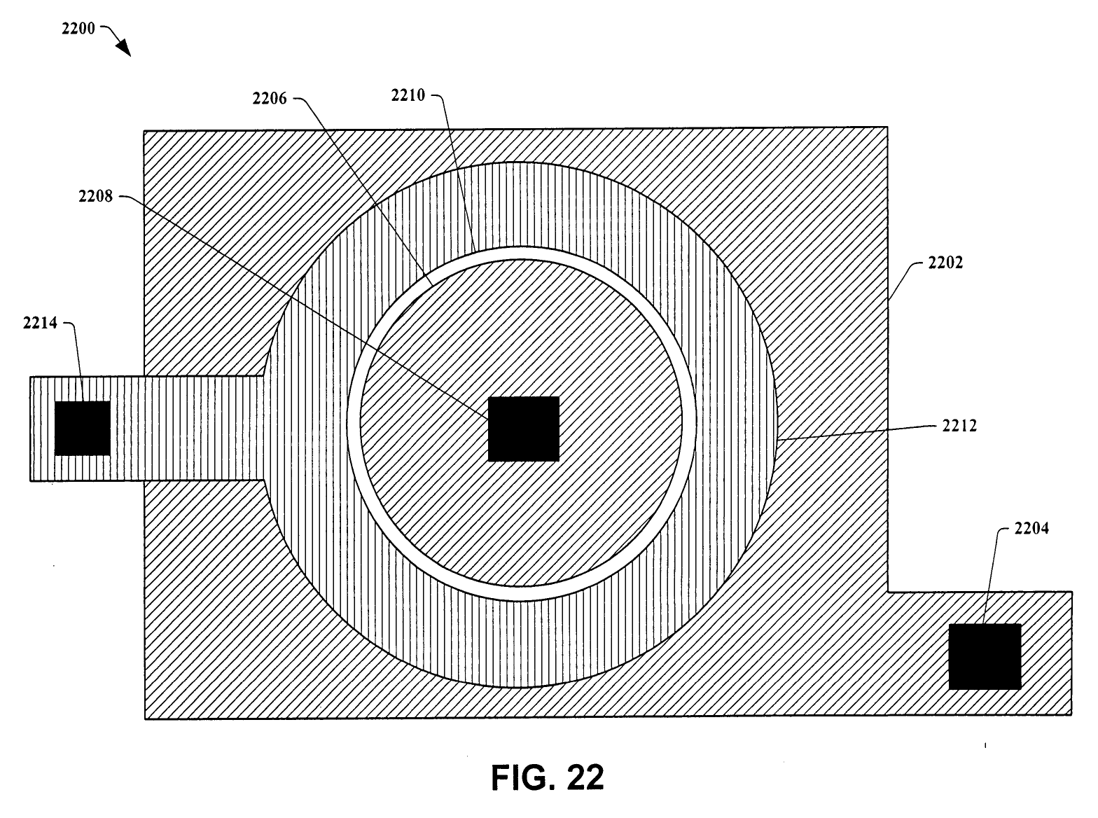

Turning to FIG. 22, a topical view illustrating a semiconductor device 2200 in accordance with an aspect of the present invention is depicted. This view shows the device 2200 without a substrate and with the only dielectric material being a gate oxide 2210. In this instance of the present invention, a first source/drain 2202 is manufactured in a rectangular shape. However, one skilled in the art can appreciate that the shape can be altered without any resulting loss of functionality. For example, the shape could be a circle, an octagon or a square and the like and still function appropriately. A first source/drain via 2204 is formed to provide a capability to make electrical contact with the first source/drain 2202. In this instance, the via 2204 is depicted on an upper surface of a tab extending from the first source/drain 2202. However, the location and orientation of the via 2204 can vary and still remain within the scope of the present invention. A second source/drain 2206 is formed on a channel (not visible). A second source/drain via 2208 is formed to provide a capability to make electrical contact with the second source/drain 2206. The shape, location and orientation of the via 2208 can be changed without altering the functionality of the device 2200. A gate 2212 is electrically isolated from the first source/drain 2202, the channel, and the second source/drain 2206. A gate via 2214 is formed to provide a capability to make electrical contact with the gate 2212. The shape, location and orientation of the via 2214 can be altered without changing the functionality of the device 2200. Although the via 2214 is depicted on a tab extending from the gate 2212, it is not necessary to have this tab in order for the device 2200 to function. The via 2214 can be formed directly to the circular portion of the gate 2212. The vias 2204, 2208, 2214 allow the device 2200 to be connected to a circuit or to another semiconductor device.

What has been described above is one or more aspects of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications and variations that fall within the spirit and scope of the appended claims. In addition, while a particular feature of the invention may have been disclosed with respect to only one of several implementations, such feature may be combined with one or more other features of the other implementations as may be desired and advantageous for any given or particular application. Furthermore, to the extent that the term “includes” is used in either the detailed description or the claims, such term is intended to be inclusive in a manner similar to the term “comprising.”

What is claimed is:

1. A semiconductor device, comprising:
a channel comprising a semiconductor material having controllable current flow properties;
a first and second source/drain interposed by the channel; and
an annular gate surrounding at least a portion of a volume of the second source/drain and at least a portion of a volume of the channel, controlling electrical flow through the channel between the first and second source/drain.

2. The device of claim 1, the second source/drain being cylindrical.

3. The device of claim 1, the channel being cylindrical.

4. The device of claim 1, the first source/drain being planar.

5. The device of claim 1, the first and second source/drain independently comprising at least one selected from the group consisting of aluminum, chromium, copper, germanium, gold, magnesium, manganese, indium, iron, nickel, palladium, platinum, silver, titanium, zinc, and alloys thereof; indium-tin oxide; polysilicon; doped amorphous silicon; and metal silicides.

6. The device of claim 1, the semiconductor material of the channel comprising a polymer material having a charge carrier doping.

7. The device of claim 6, the polymer material comprising at least one from a group consisting of polyacetylene; polyphenylacetylene; polydiphenylacetylene; polyaniline; poly(p-phenylene vinylene); polythiophene; polyporphyrins; porphyrinic macrocycles, thiol derivatized polyporphyrins; polymetallocenes, polyphthalocyanines; polyvinylenes; and polystiroles.

8. The device of claim 1, the annular gate comprising a polycrystalline silicon material.

9. The device of claim 1, the second source drain and the annular gate interposed by a dielectric material.

10. The device of claim 9, the dielectric material comprising an oxide material.

11. The device of claim 1, the annular gate and the channel interposed by a dielectric material.

12. The device of claim 11, the dielectric material comprising an oxide material.

13. A method of fabricating a semiconductor device, comprising:
forming a first source/drain;
forming a channel comprising a semiconductor material on the first source/drain;
forming a second source/drain on the semiconductor material; and
forming an annular gate surrounding at least a portion of a volume of the channel and at least a portion of a volume of the second source/drain.

14. The method of claim 13, the first and second source/drain independently comprising at least one selected from the group consisting of aluminum, chromium, copper, germanium, gold, magnesium, manganese, indium, iron, nickel, palladium, platinum, silver, titanium, zinc, and alloys thereof; indium-tin oxide; polysilicon; doped amorphous silicon; and metal silicides.

15. The method of claim 13, wherein the semiconductor material of the channel comprising a polymer material having a charge carrier doping.

16. The method of claim 15, wherein the polymer material comprising at least one selected from a group consisting of polyacetylene; polyphenylacetylene; polydiphenylacetylene; polyaniline; poly(p-phenylene vinylene); polythiophene; polyporphyrins; porphyrinic macrocycles, thiol derivatized polyporphyrins; polymetallocenes, polyphthalocyanines; polyvinylenes; and polystiroles.

17. The method of claim 13, wherein the annular gate comprising a polycrystalline silicon material.

18. A method of fabricating a semiconductor device, comprising:
forming a first source/drain;
forming a channel comprising a semiconductor material on the first source/drain;
forming a second source/drain on the semiconductor material;
depositing a dielectric material layer on the first and second source/drain and the channel; and
forming an annular gate surrounding at least a portion of a volume of the channel and at least a portion of a volume of the second source/drain with the dielectric material interposed between the annular gate and both the channel and the second source/drain.

19. A system for manipulating electrical current comprising:
means for connecting circuitry to a first and second source/drain interposed by a channel comprising a polymer material; and
means for controlling current flow through the channel via an annular gate surrounding at least a portion of the second source/drain and at least a portion of the channel.

20. A computer comprising the semiconductor device of claim 1.

21. A handheld electronic device comprising the semiconductor device of claim 1.

22. An amplification device comprising at least one of the semiconductor device(s) of claim 1.

23. A communication device comprising at least one of the semiconductor device(s) of claim 1.

24. A memory device comprising at least one of the semiconductor device(s) of claim 1.
